(19) United States
(12) Patent Application Publication
(10) Pub. No.: US 2016/0191041 A1
(43) Pub. Date: Jun. 30, 2016

(54) Circuit and Method for Power-On Reset of an Integrated Circuit

(71) Applicant: Shine C. Chung, San Jose, CA (US)

(72) Inventor: Shine C. Chung, San Jose, CA (US)

(21) Appl. No.: 14/985,095

(22) Filed: Dec. 30, 2015

Related U.S. Application Data
(60) Provisional application No. 62/097,611, filed on Dec. 30, 2014.

(51) Int. Cl. H03K 17/22; G05F 1/46; H03K 3/356

(52) U.S. Cl. CPC H03K 17/223; H03K 3/356104; G05F 1/463

(57) ABSTRACT

A Power-On-Reset circuit is disclosed to generate a POR signal when a supply voltage (e.g., VDD) is ramping up and has exceeded a threshold voltage. The POR circuit can include a startup circuit, a reference generator, a comparator, and a latch. The startup circuit can be initialized into an on state and can serve to turn on all other circuit blocks of the POR circuit. The reference generator can then generate at least one temperature-compensated reference voltage. The comparator can compare the reference voltage with the supply voltage or a supply voltage following signal to output a Power-On-Signal (POS). After the POS has been asserted and latched, the startup circuit can be reset and the other circuit blocks of the POR circuit can be powered down.

### CROSS-REFERENCE TO RELATED APPLICATION

This application claims priority benefit of U.S. Provisional Patent Application No. 62/097,611, filed on Dec. 30, 2014 and entitled “Circuit and Method of A Power-On Reset,” which is hereby incorporated herein by reference.

### BACKGROUND OF THE INVENTION

A Power-On-Reset (POR) circuit is to generate a signal (or pulse) upon powering up to reset all latches, flip-flops, or registers in an integrated circuit. Sometime, this signal can also be used to startup analog circuits, to do self-calibrations, or to read data from memories. For analog or memory types of applications, the POR signal has more restricted requirements, such as being triggered at a more precise target voltage level or being generated with a precise pulse width.

Powering up an integrated circuit takes about 10 us to 100 ms from ground to full supply voltage VDD in most cases, depending on particular power supplies built into a system. The POR needs to be generated reliably with different ramping rates. The POR also needs to be generated when the supply voltage VDD is higher than the threshold voltage (˜0.7V) of the MOS devices when the latches or flip-flops are fully functional to ensure reliable reset operation. The requirements of a good POR circuit are: (a) reliable operation with different ramping rate; (b) insensitive to Process, Voltage, and Temperature (PVT) variations, (c) small area, (d) low operation power and zero standby power except leakage, and (e) PRO signal generation when the supply voltage reaches a pre-determined level, target voltage level. The precision of the target voltage level can be important especially when this voltage level is used to trigger sense amplifier or analog functions. The functionality of a POR is rather simple and the requirements are very straight-forward. However, most POR circuits have difficultly satisfying these requirements.

FIG. 1(a) shows a conventional POR circuit 10 known in the art. The POR circuit 10 has a delay circuit 11, which includes at least one resistor 12 and one capacitor 13, and followed by one or more inverters 15 and 17 connected in series, namely the output of the delay circuit 11 is an input of the inverter 15 and the output of the inverter 15 is an input of the inverter 17. The delay circuit 11 is to delay the ramping up the supply voltage VDD so that the output of the inverter 15 can follow VDD once VDD is higher than the threshold voltage of an NMOS, and then can go down when the VDD is higher than the trip point of an inverter. The output of the inverter 17 is a Power-On-Signal (POS) that goes up when VDD reaches a voltage threshold. FIG. 1(b) shows waveforms of the signals in FIG. 1(a) during VDD ramping up.

The POR circuit showed in FIG. 1(a) has many drawbacks. First, the delay time of the delay circuit 11 needs to cope with the VDD ramping rate of between 10 us to 100 ms. In today's integrated circuit technology, resistors and capacitors used in the delay circuit would be very large to generate delay time comparable to 100 ms. This unfortunately consumes lots of silicon area and increase costs substantially. Moreover, the generation of POR or POS will depend on the Process, Voltage, and Temperature (PVT) variations by using an inverter as a triggering device. If the POR is generated when the VDD is not high enough that most of circuits are not functional properly, insufficient reset may happen that can jeopardize normal logic operations. In other words, this circuit can not generate a precision POR signal based on target voltage level during VDD ramping. There are some variations of using diodes to charge capacitors in the delay circuits, but the same drawbacks are not overcome.

Thus, there is a need an improved POR circuit that depends not on delaying the supply voltage but rather on a voltage level (i.e. target voltage level) the supply voltage reaches, where the silicon area needs is small and thus cost effective. Active power consumption should be low to save power, while standby current needs to be almost zero, except for junction leakage. A POR signal also should be generated when VDD reaches a predetermined voltage level, target voltage level, regardless of PVT variations for analog or memory types of applications. Accordingly, there remains a need for an improved POR circuit to better meet design requirements.

### SUMMARY

Embodiments of Power-On-Reset (POR) circuit using at least one reference voltage and comparator are disclosed. The POR circuit can generate a POR signal when a supply voltage reaches a target voltage level. In one embodiment, the POR circuit generates ramp rate independent POR signal. The POR circuit can also have reliable operation over various ramp rates and/or Process, Voltage, and Temperature (PVT) conditions. The POR circuit can also be implemented in a small area, and can have a low active current and nearly zero standby current (except junction leakage). Advantageously, the POR circuit can have high performance at low cost. The POR circuit is well suited for analog or memory types of integrated circuit application.

According to one embodiment, the POR circuit has at least one reference generator and a comparator. The POR circuit can also include a startup circuit and/or a latch. The reference generator can generate at least one voltage reference with compensated temperature coefficient and/or a supply voltage following signal. The comparator can compare the reference voltage with the supply voltage or the supply voltage following signal to generate a Power-On-Signal (POS), when the supply voltage ramps up to a target voltage threshold. The startup circuit can ensure the proper generation of the reference voltages upon powering up and can be turned off when POS signal is generated. The latch can preserve the power-on state when POS signal is asserted to further power down the other circuit blocks.

The invention can be implemented in numerous ways, including as a method, system, device, or apparatus (including graphical user interface and computer readable medium). Several embodiments of the invention are discussed below.

As a Power-On-Reset (POR) circuit integrated in an integrated circuit, one embodiment can, for example, include at least: a reference generator to generate at least one temperature-compensated reference voltage; and a comparator to compare the reference voltage with a supply voltage or a supply voltage following signal, and to produce a comparison signal. The POR circuit can generate a Power-On Signal (POS) based on the comparison signal of the comparator.

As a Power-On-Reset (POR) circuit, one embodiment can, for example, include at least a reference generator, a comparator, a startup circuit, and a latch. The reference generator can generate at least one voltage reference with compensated temperature coefficient and/or a supply voltage following signal. The comparator can compare the reference voltage with supply voltage or the supply voltage following signal to generate a Power-On-Signal (POS), when the supply voltage ramps up to a target voltage threshold (or target voltage level), which is the same or related to the voltage reference (or reference level). The startup circuit can ensure the proper generation of the reference voltages upon powering up and can be turned off when POS is generated. The latch can preserve the power-on state when POS is asserted to further power down the other circuit blocks.

As an electronic system, one embodiment can, for example, include at least a processor, and a plurality of integrated circuits operatively connected to the processor. At least one of the processor or integrated circuits can include at least one Power-On-Reset (POR) circuit. One embodiment of the POR circuit can, for example, include at least a reference generator, a comparator, a startup circuit, and a latch. The reference generator can generate at least one voltage reference with compensated temperature coefficient and/or a supply voltage following signal. The comparator can compare the reference voltage with the supply voltage or the supply voltage following signal to generate a Power-On-Signal (POS), when the VDD ramps up to a target voltage threshold, which can be the same or related to (e.g., offset from) the voltage reference. The startup circuit can ensure the proper generation of the reference voltages upon powering up and can be turned off when POS is generated. The latch can preserve the power-on state when POS is asserted to further power down the other circuit blocks.

As a method for providing a Power-On-Reset (POR) signal, one embodiment can, for example, include at least the following: providing a startup circuit to set other circuit blocks into on states during a supply voltage ramping up: providing a reference generator to generate a temperature-compensated reference voltage; providing a comparator to compare the reference voltage with the supply voltage VDD or the supply voltage following signal; and generating a Power-On-Signal (POS) at or from the output of the comparator when the supply voltage ramping up exceeds a target voltage threshold, which can be the same or related to (e.g., offset from) the voltage reference.

As a method for generating a Power-On-Signal (POS) in an integrated circuit, one embodiment can, for example include at least: producing a temperature-compensated reference voltage; comparing the reference voltage with a supply voltage or a supply voltage following signal; and generating a Power-On-Signal (POS) when the comparing determines that the supply voltage or a supply voltage following signal has sufficiently ramped up after being turned on.

### BRIEF DESCRIPTION OF THE DRAWINGS

The present invention will be readily understood by the following detailed descriptions in conjunction with the accompanying drawings, wherein like reference numerals designate like structural elements, and in which:

FIG. 1(a) shows a conventional Power-On-Reset circuit.

FIG. 1(b) shows timing waveforms of the POR circuit in FIG. 1(a).

FIG. 2 shows circuit blocks of a POR circuit according to one embodiment.

FIG. 3(a) shows a single-end comparator circuit according to one embodiment.

FIG. 3(b1) shows a two-input comparator circuit according to another embodiment.

FIG. 3(b2) shows timing waveforms of the comparator circuit in FIG. 3(b1).

FIG. 4(a) shows a reference generator circuit according to one embodiment.

FIG. 4(b) shows a reference generator circuit according to another embodiment.

FIG. 5 shows a startup circuit according to one embodiment.

FIG. 6(a) shows a reference generator with a startup circuit according to one embodiment.

FIG. 6(b) shows a reference generator with a startup circuit according to another embodiment.

FIG. 7 shows a reference generator and a two-input comparator according to one embodiment.

FIG. 8 shows a procedure to generate a Power-On-Signal according to one embodiment.

FIG. 9 shows a block diagram of an electronic system including at least one integrated circuit that has a POR circuit according to one embodiment.

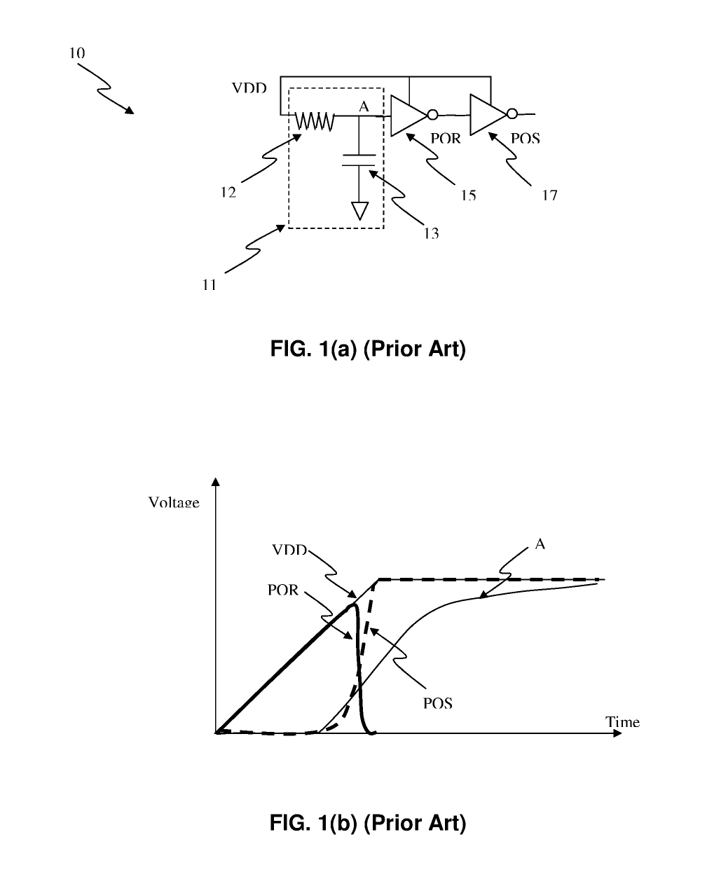

### DETAILED DESCRIPTION OF EMBODIMENT OF THE INVENTION

Embodiments disclosed herein use at least one reference generator and comparator to generate a Power-On-Signal (POS) that depends on a target voltage level of a ramping up supply voltage (e.g., VDD). Since the POS signal is not generated dependent on the delay of supply voltage ramping, but is instead generated dependent on a reference voltage of the supply voltage. The operation can be very reliable and consume only a small area (i.e., die area). A startup circuit can turn on the reference generator and comparator during ramping up of the supply voltage and can shutdown circuit blocks once the POS is generated and latched to reach nearly zero standby current, except junction leakage.

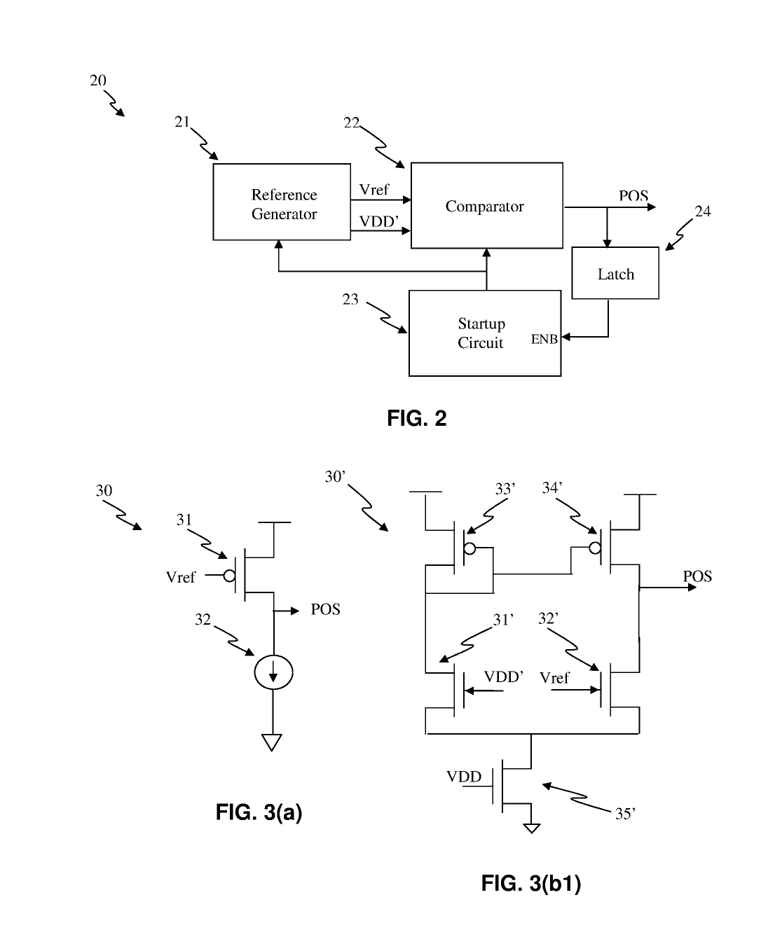

FIG. 2 shows a POR circuit 20 according to one embodiment The POR circuit 20 has a startup circuit 23 initialized into an on state and to turn on all other circuit blocks during powering up. The POR circuit 20 has a reference generator 21 generating a reference voltage Vref and/or a VDD following signal VDD′ coupled to a comparator 22. The output of the comparator 22 is a Power-On-Signal (POS). Once the POS is asserted after VDD ramping up to a target voltage level that depends on Vref, the POS is latched and can also disable the startup circuit 23, which further powers down the other circuit blocks of the POR circuit 20. The reference voltage is more desirable a temperature-compensated voltage that has a reduced temperature coefficient. A bandgap reference can be provided in one embodiment of the reference generator. A sub-bandgap (i.e. a fraction of the bandgap voltage) reference can be another embodiment of the reference generator. The VDD following signal VDD′ can be at VDD or at VDD with a voltage drop, such as one threshold voltage drop of one junction diode or MOS-connected diode. The VDD following signal VDD′ can also be a voltage divider output of VDD or VDD through a diode threshold drop in another embodiment. The comparator 22 can compare two signals to assert a POS when VDD ramps up and exceeds a target voltage threshold, or Vref. The latch 24 can be used to store the POS on state and can be further be used to reset the startup circuit 23. In one embodiment, the latch 24 can be implemented as a pair of cross-coupled inverters with the POS end coupled to a large capacitor to ground and another end coupled to another large capacitor to a supply voltage. The startup circuit 23 is to ensure the reference generator and the comparator can be started with on states so that the whole POR circuit can function properly.

In another embodiment, the reference voltage can be used as POS if the reference voltage can rise abruptly when supply voltage (e.g., VDD) ramping exceeds a threshold. In some embodiments, the reference voltage or the supply voltage following signal can go through at least one level shifter to the inputs of the comparator, such as a source follower or emitter follower with at least one MOS or resistor as a pulldown device. In other embodiments, the startup circuit 23 or the latch 24 can be omitted.

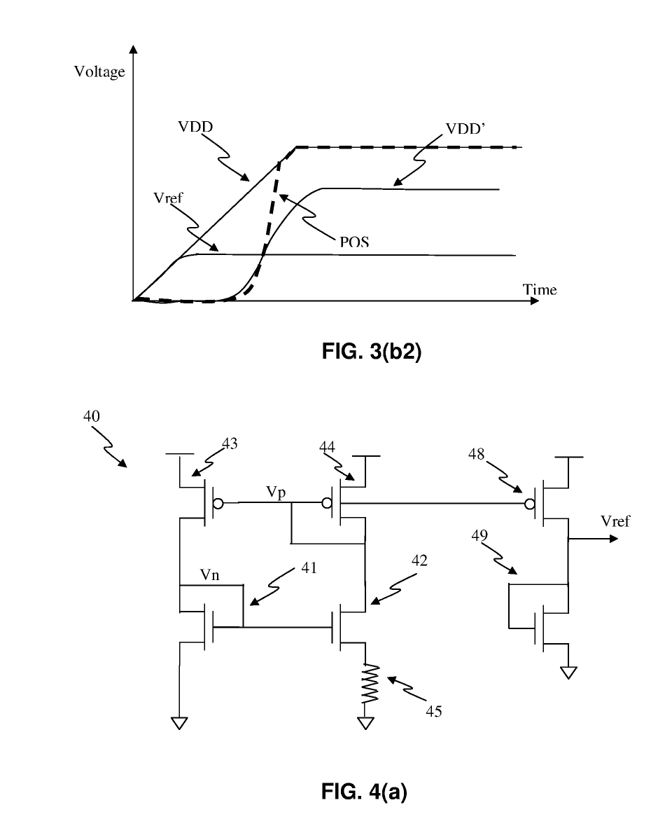

FIG. 3(a) shows a single-end comparator 30 according to one embodiment. The comparator 30 has a PMOS 31 and a current source 32. The gate of the PMOS 31 is coupled to a voltage reference Vref. The source of the PMOS 31 is coupled to VDD. The drain of the PMOS 31 is coupled to a current source 32. The comparator 30 is essentially a single-transistor amplifier. When the VDD in ramping from low to one |Vtp| above Vref, the POS switches drastically from low to high. Essentially, this is a single-transistor amplifier to compare Vref with VDD−|Vtp| and output a POS signal. The current sources can be a constant current source, compensated current source with reduced temperature coefficient, or a PTAT (Proportional To Absolute Temperature) current source in different embodiments. The current source 32 can also be implemented as a MOS with the gate coupled to the other MOS for current mirroring.

FIG. 3(b1) shows a two-input comparator 30′ according to one embodiment. The comparator is a very common differential amplifier that has two PMOS pullups 33′ and 34′, two NMOS inputs 31′ and 32′, and a summing MOS 35′. The gates of the two NMOS inputs 31′ and 32′ are coupled to VDD′ and Vref, respectively. The sources of the NMOS 31′ and 32′ are coupled to the drain of the summing MOS 35′, whose gate is coupled to VDD and whose source is coupled to ground. The sources of the PMOS 33′ and 34′ are coupled to VDD. The drains of the PMOS 33′ and 34′ are coupled to the drains of NMOS 31′ and 32′, respectively. The gate of PMOS 33′ is coupled to its drain and also coupled to the gate of PMOS 34′ to constitute as a “current mirror amplifier.” The drain of the PMOS 34′ is the output POS.

FIG. 3(b2) shows timing waveforms of the various nodes in FIG. 3(b1), as an example. During VDD ramp up, the reference voltage Vref goes from ground to a stable voltage level, while VDD′ goes from ground to a voltage drop from VDD after VDD exceeds MOS threshold voltage. When VDD reaches a threshold that VDD′ is higher than Vref, a POS signal will be asserted. The POS can be asserted before or after VDD reaches full swing. The voltage drop of VDD′ to VDD is normally a fixed voltage, a threshold voltage of diode or MOS. By adjusting the Vref and the voltage drop in VDD′, the target voltage threshold of the POS turn-on voltage can be controlled.

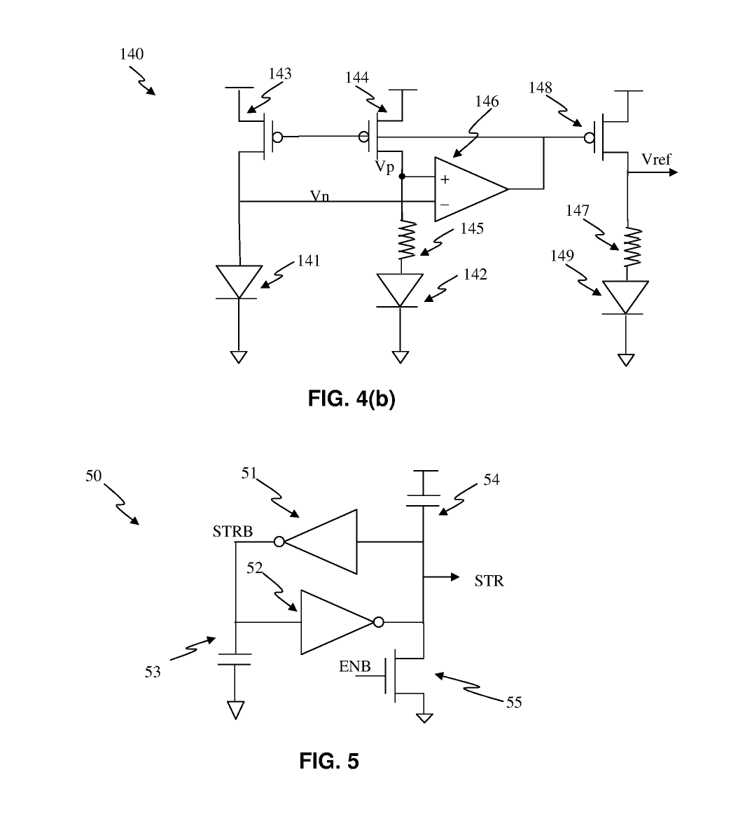

FIG. 4(a) shows a reference generator 40 according to one embodiment. The bandgap reference circuit 40 is a reference generator. The circuit showed in FIG. 4(a) is commonly referred as a CMOS bandgap that includes a CMOS PTAT (Proportional To Absolute Temperature) and an output stage. The CMOS PTAT circuit has two NMOS 41 and 42 with the drains coupled to the drains of two PMOS 43 and 44, respectively. The gate of MOS 41 is coupled to its drain, and the source is coupled to ground. The gate of MOS 42 is coupled to the gate of MOS 41 and the source is coupled to a resistor 45 which is further coupled to ground. The sources of the PMOS 43 and 44 are coupled to VDD. The gate of the PMOS 44 is coupled to its drain and is also coupled to the gate of PMOS 43. By using this configuration with proper device sizes, the current flowing through PMOS 43 or 44 can be proportional to the inversion of the transconductance of NMOS 41 and 42, or about proportional to the absolute temperature. The output stage of CMOS bandgap has a PMOS pullup 48, which is current mirrored from the PMOS 43 or 44, and an NMOS 49 pulldown. The drain of the PMOS 48 is coupled to the drain of the NMOS 49 which is connected as a diode. The positive temperature coefficient of PMOS 48 can charge the NMOS 49 and compensate the negative temperature of the threshold voltage in NMOS 49. Thus, a simple bandgap reference can be created using all CMOS devices, despite its precision not being as good as the bandgap that uses bipolar devices or junction diodes.

There are many variations in the FIG. 4(a) in accordance of different embodiments. For example, a resistor in the CMOS PTAT can be between the source of a PMOS and VDD, instead of between the source of a NMOS and ground (e.g., resistor 45). The NMOS and PMOS can be sized differently to achieve more suitable results. The pulldown device 49 in the output of CMOS bandgap can be a NMOS, PMOS, junction diode, resistor, or combination thereof.

FIG. 4(b) shows a bandgap reference circuit 140 according to another embodiment. The bandgap reference circuit 140 is a reference generator to generate approximately 1.2V. The circuit 140 shown is only one of the many bandgap reference circuits in use today. The bandgap 140 has an operational amplifier 146 that has two inputs Vn and Vp, Vn coupled to a diode 141 to ground and Vp coupled to a resistor 145 and then to another diode 142 to ground. The diode 141 and resistor 145 have PMOS pullups 143 and 144, respectively, to VDD. The gate of PMOS pull-ups 143 and 144 are coupled to the output of the amplifier 146. The output stage of this circuit 140 has a PMOS pullup 148, current mirrored from PMOS 144 to charge a resistor 147 and then to another diode 149 to ground. This circuit 140 uses two junction diodes 141 and 142 with different sizes and the resistor 145 to generate a PTAT current by using the amplifier 146 to force two nodes, Vp and Vn, equal. The current flowing through the PMOS 143 and 144 can, therefore, be a PTAT current. The PTAT current can be used to charge the resistor 147 providing a positive temperature coefficient to compensate the negative temperature coefficient of the junction diode 149. In another embodiment, the bandgap reference circuit 140 can also be a sub-bandgap circuit to generate a fraction of the bandgap voltage for a reference Vref.

FIG. 5 shows a startup circuit 50 to provide a preferential state during powering up, according to one embodiment. The startup circuit 50 has two cross-coupled inverters 51 and 52, whose output nodes are coupled to two capacitors 53 and 54, respectively, and which are further coupled to VDD and ground, respectively. During the powering up, STRB will be coupled low and STR will be coupled high to reach a preferred on state because of the capacitors 53 and 54. The NMOS 55 is a reset device with gate coupled to ENB, source coupled to ground, and drain coupled to STR. The ENB can be coupled to POS to reset the startup circuit 50 after POS is asserted. After the startup circuit 50 is reset, other circuit blocks used by a POR circuit can be powered down. Also, in one embodiment, the startup circuit 50 without the NMOS 55 reset device can be used as the latch 24 shown in FIG. 2.

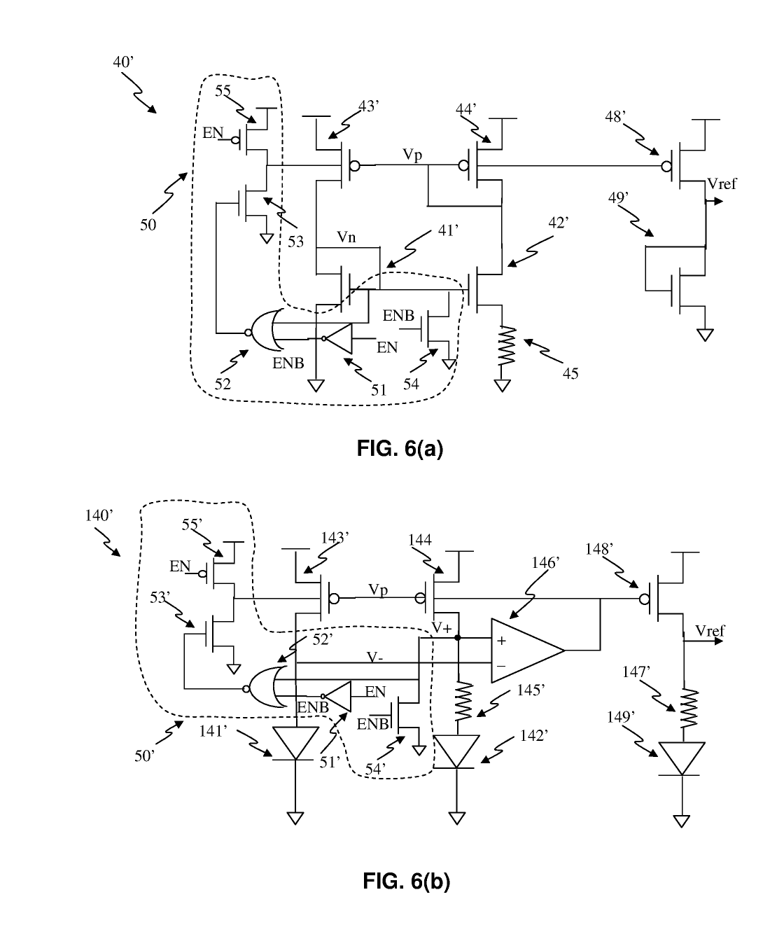

FIG. 6(a) shows a CMOS bandgap circuit 40′ with a startup circuit 50 enclosed by a dash line. The CMOS bandgap circuit 40′ shown is the same as the circuit in FIG. 4(a), except with the startup circuit 50 included. The startup circuit 50 includes a pullup PMOS 55, a pulldown NMOS 54, an inverter 51, a two-input NOR 52, and a pulldown NMOS 53. If the enable (EN) is low, the nodes Vp and Vn could be pulled up to VDD and pulled down to ground, respectively, so that the cross-coupled MOS 43′, 44′, 41′, and 42′ would be turned off. If the enable (EN) is high, the PMOS pullup 55 and NMOS pulldown 54 will be cut off. If the node Vn is initially low during powering up, the node Vp can be pulled down by high in the output of the NOR 52 and pulldown NMOS 53 to generate currents for PMOS 43′ and 44′ and to initialize the CMOS bandgap circuit 40′ into an on state. The startup circuit 50 serves to initialize the CMOS PTAT into an on state, when the CMOS PTAT has two stable states, one on and another off.

FIG. 6(b) shows another bandgap circuit 140′ with a startup circuit 50′ enclosed by a dash line. The bandgap circuit 140′ shown is the same as the circuit in FIG. 4(b), except with a startup circuit 50′ included. The startup circuit 50′ includes a pullup PMOS 55′, a pulldown NMOS 54′, an inverter 51′, a two-input NOR 52′, and a pulldown NMOS 53′. If the enable (EN) is low, the nodes Vp and V+ could be pulled up to VDD and pulled down to ground, respectively, so that the PMOS 143′ and 144′ would be turned off. If the enable (EN) is high, the PMOS pullup 55′ and the NMOS pulldown 54′ will be cut off. If the node V+ is initially low during powering up, the node Vp can be pulled down by high in the output of the NOR 52′ and then pulldown NMOS 53′ to generate currents for PMOS 143′ and 144′ and to initialize the bandgap circuit 140′ into an on state. The startup circuit 50′ serves to initialize the PTAT generator into an on state, when the PTAT generator has two stable states, one on and another off. The operational amplifier 146′ can also be powered up and down by the startup circuit 50′.

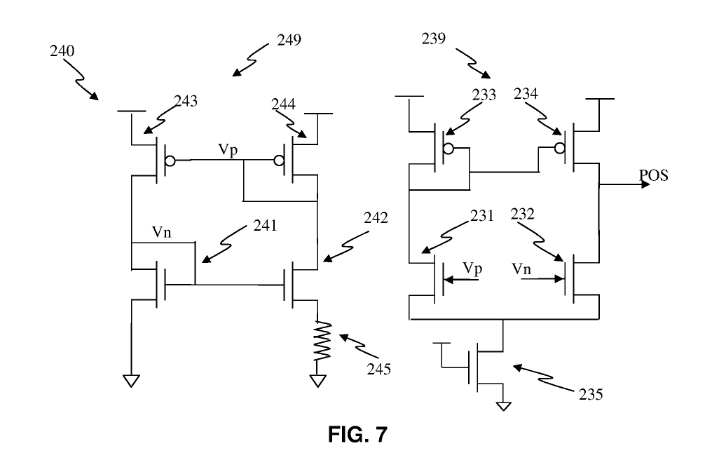

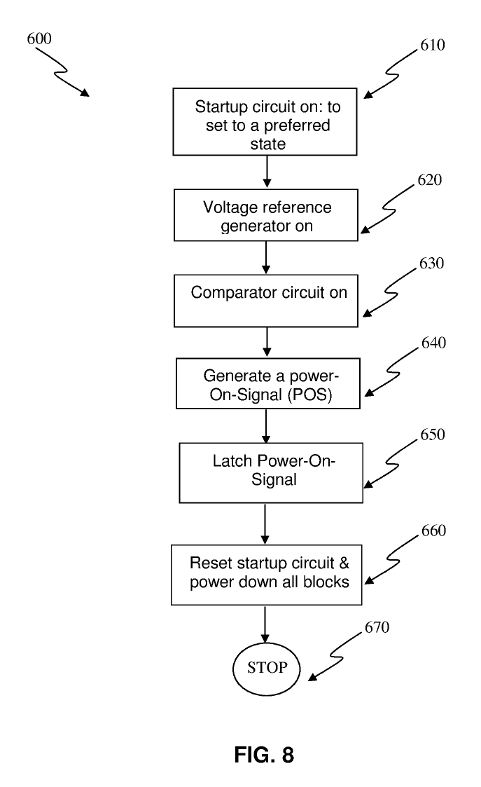

FIG. 7 shows a POR circuit 240 including a CMOS PTAT 249 and a two-input comparator 239 to generate POS, according to another embodiment. The CMOS PTAT 249 includes two pairs of NMOS 241 and 242 and PMOS 243 and 244 configured as cross-coupled current-mirror devices with a resistor 245 coupled to the source of NMOS 242 to ground. The gate voltages of the MOS-connected as diode in NMOS 241 and PMOS 244 can serve as a Vref and VDD′ signal, respectively, which are further coupled to the inputs of a current-mirror amplifier 239 that includes two NMOS inputs 231 and 232, two PMOS pull-ups 233 and 234, a summing NMOS 235. The gate of PMOS 233 is coupled to the drain and further coupled to the gate of the PMOS 234. The drain of the PMOS 234 is a POS signal. The triggering of POS depends on the size ratio of PMOS and NMOS in the CMOS PTAT 249 and the resistor 245. Hence, the target voltage level is not as precise as from a reference voltage generator.

FIG. 8 depicts a method 600 of generating a Power-On-Signal (POS) in a flow chart according to one embodiment. In the first step 610, a startup circuit is turned on into a preferred state during powering up. In the second step 620, a reference generator is turn on to generate at least one reference voltage. In the third step 630, a comparator is turned on to compare one reference voltage with VDD or a VDD following signal. In the fourth step 640, a Power-On-Signal (POS) can be generated when VDD reaches a predetermined, or target threshold voltage. In the fifth step 650, the POS is latched. In the sixth step 660, the startup circuit is reset by POS and other circuit blocks are powered down to consume virtually no current. Then the operation of the POR circuit finishes in step 670.

The block diagrams shown in FIGS. 4(a), 4(b), 5, 6(a), 6(b), and 7 are for illustrative purposes. The actual circuit and logic implementations may vary. Similarly, the procedures described in FIG. 8 are for exemplifier purposes. The detailed implementation in the procedures may vary. For example, some steps may be skipped. Some steps can be in different order. There can be many embodiments of the circuit, logic, block diagram, and procedures and that are still within the scope of this invention for those skilled in the art.

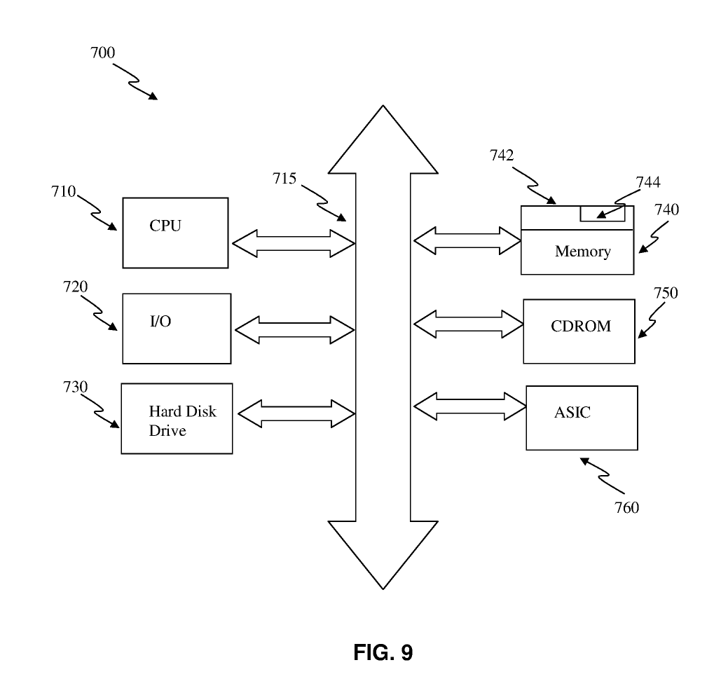

FIG. 9 shows an electronic system 700 according to one embodiment. The electronic system 700 can, for example, pertain to a computer or a processor system that includes at least one CPU and a plurality of peripheral devices. The CPU and/or at least one peripheral device include at least one POR circuit. The computer system can include a Central Process Unit (CPU) 710, which communicate through a common bus 715 to various memory and peripheral devices such as I/O 720, hard disk drive 730, CDROM 750, memory 740, and other ASIC 760. CPU 710 generally is a microprocessor, a digital signal processor, or other programmable digital logic devices. Memory 740 can be a conventional memory such as SRAM, DRAM, flash, or other kinds of emerging memory, and is preferably constructed as an integrated circuit, which includes at least one memory array 742 having at least one memory cells 744. The memory 740 typically interfaces to CPU 710 through a memory controller. If desired, the memory 740 may be combined with the processor, for example CPU 710, in a single integrated circuit. The POR circuit in this invention can be integrated into at least one circuit blocks, such as CPU 710, I/O circuit 720, hard disk drive 730, memory 740, and ASIC 760, etc.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A Power-On Reset (POR) circuit integrated in an integrated circuit, the POR circuit comprising:
a reference generator to generate at least one temperature-compensated reference voltage;
a comparator to compare the reference voltage with a supply voltage or a supply voltage following signal, and to produce a comparison signal,
wherein the POR circuit generates a Power-On Signal (POS) based on the comparison signal of the comparator.

2. A POR circuit as recited in claim 1, wherein the POR circuit comprises:
a startup circuit that is initialized into an on state to turn on the reference generator and the comparator during a ramping up of the supply voltage.

3. A POR circuit as recited in claim 2, wherein the POR circuit comprises:
a latch circuit to latch a signal used to configure the startup circuit to turn off the reference generator and the comparator after the POS has been generated.

4. A Power-On Reset (POR) circuit integrated in an integrated circuit comprises:
a startup circuit to be initialized into an on state to turn on other circuit blocks during a supply voltage ramping up;
a reference generator to generate at least one temperature-compensated reference voltage;
a comparator to compare the reference voltage with a supply voltage following signal; and
wherein a Power-On Signal (POS) can be generated from the output of the comparator when the supply voltage that is ramping up exceeds a target voltage threshold depending on the reference voltage.

5. A POR circuit as recited in claim 4, wherein the supply voltage following signal tracks the ramping up of the supply voltage but with about a threshold voltage drop of at least one junction diode or CMOS-connected diode.

6. A POR circuit as recited in claim 4, wherein the reference generator and the comparator are powered down after the POS is generated.

7. A POR circuit as recited in claim 4, wherein the reference generator comprises at least a bandgap reference circuit that uses diodes or MOS in a PTAT (Proportional To Absolute Temperature) generator.

8. A POR circuit as recited in claim 4, wherein the reference generator comprises at least a sub-bandgap reference circuit that uses diodes or MOS in a PTAT (Proportional To Absolute Temperature) generator to generate a fraction of a bandgap reference voltage.

9. A POR circuit as recited in claim 4, wherein the reference generator has at least a level shifter coupled to an output to shift one diode voltage down by using an emitter follower or source follower configured device.

10. A POR circuit as recited in claim 4, wherein the comparator includes a single-end comparator to compare the reference voltage to compare with the supply voltage and to output the POS.

11. A POR circuit as recited in claim 4, wherein the comparator includes a differential amplifier having inputs from at least the reference voltage and/or the voltage source following signal and to output the POS.

12. An electronic system, comprising:
at least one integrated circuits; at least one of the integrated circuits having a Power-On-Reset (POR) circuit,
wherein the POR circuit comprises:
a startup circuit to be initialized into an on state and to turn on other circuit blocks within the POR circuit during a supply voltage ramping up;
a reference generator to generate at least one temperature-compensated reference voltage;
a comparator to compare the reference voltage with a supply voltage following signal; and
wherein a Power-On Signal (POS) is generated from the output of the comparator when the supply voltage is ramping up and has exceeded a target voltage level, the target voltage level being dependent on the reference voltage.

13. An electronic system as recited in claim 12, wherein the supply voltage following signal tracks the ramping up of the supply voltage but with about a threshold voltage drop of at least one junction diode or CMOS-connected diode.

14. An electronic system as recited in claim 12, wherein the other circuit blocks are powered down after POS is generated.

15. An electronic system as recited in claim 12, wherein reference generator comprises a bandgap reference circuit that uses junction diodes or MOS in a PTAT (Proportional To Absolute Temperature) generator.

16. An electronic system as recited in claim 12, wherein reference generator comprises a sub-bandgap reference circuit that uses junction diodes or MOS in the PTAT (Proportional To Absolute Temperature) generator to generate a fraction of a bandgap reference voltage.

17. An electronic system as recited in claim 12, wherein the reference generator comprises at least one level shifter to shift the voltage one diode voltage down by using a device configured as an emitter follower or source follower.

18. An electronic system as recited in claim 12, wherein the comparator comprises a single-end comparator to use a reference voltage to compare with the supply voltage and to output the POS.

19. An electronic system as recited in claim 12, wherein the comparator has a differential amplifier having inputs from at least one reference voltage and/or the supply voltage following signal and to output the POS.

20. A method for generating a Power-On-Signal (POS) in an integrated circuit, the method comprising:
producing a temperature-compensated reference voltage;
comparing the reference voltage with a supply voltage or a supply voltage following signal; and
generating a Power-On-Signal (POS) when the comparing determines that the supply voltage or a supply voltage following signal has sufficiently ramped up after being turned.
